(19) United States
(12) Patent Application Publication
(10) Pub. No.: US 2008/0151674 A1
(43) Pub. Date: Jun. 26, 2008

(54) SEMICONDUCTOR MEMORY DEVICE AND METHOD OF DRIVING THE SAME

(75) Inventors: Munetoshi OHATA, Tokyo (JP); Kazuhiro TERAMOTO, Tokyo (JP); Noriaki MOCHIDA, Tokyo (JP)

Correspondence Address: YOUNG & THOMPSON, 209 Madison Street, Suite 500, ALEXANDRIA, VA, 22314, US

(73) Assignee: ELPIDA MEMORY, INC., Tokyo (JP)

(21) Appl. No.: 11/959,491

(22) Filed: Dec. 19, 2007

(30) Foreign Application Priority Data
Dec. 25, 2006 (JP) 2006-348112

(51) Int. Cl. G11C 5/14

(52) U.S. Cl. 365/227

(57) ABSTRACT

A semiconductor memory device includes a first circuit which generates a first potential lower than the external power supply voltage, a second circuit which generates a second potential lower than the first potential, a capacitor charged to the first potential, a bit line connected to a memory cell, a sense amplifier which performs sense operation to amplify a potential on the bit line to the second potential, and a connection control circuit which connects the first circuit to the sense amplifier within a first time period from a start of the sense operation, and which connects the second circuit to the sense amplifier after the lapse of the first time period. The first circuit is enabled before the start of the sense operation and is disabled after the completion of charging of the capacitor, and the output of the first circuit is thereby set in a floating state.

This application is based upon and claims the benefit of priority from Japanese patent application No. 2006-348112, filed on Dec. 25, 2006, the disclosure of which is incorporated herein in its entirety by reference

### BACKGROUND OF THE INVENTION

1. Field of the Invention

The present invention relates to a semiconductor memory device and a method of driving the semiconductor memory device. More particularly, the present invention relates to a semiconductor memory device which has a memory cell array and sense amplifiers operating on an internal stepped-down voltage generated from an external power supply voltage, and for which a charge-sharing overdrive scheme to accelerate sensing speed is used, and to a method of driving such a semiconductor memory device.

2. Description of the Related Art

In general, in a semiconductor memory device to which an external power supply voltage is supplied from the outside, an internal stepped-down voltage having an absolute value smaller than that of an external power supply voltage is generated in an on-chip power supply circuit to be supplied as a power supply voltage to a memory cell array and sense amplifiers in the semiconductor memory device. This is done chiefly for the purpose of reducing the power consumption and ensuring reliability. In a case where an internal stepped-down voltage is used, however, the amplitude of a readout signal from a memory cell is reduced and the operating speed of the sense amplifier is lowered due to the reduced drive voltage to the sense amplifier.

For semiconductor memory devices, an overdrive technique is used for increasing the sensing speed in the sense operation to a memory cell. In the overdrive technique, a voltage supplied to a sense amplifier in an initial stage of sense operation is set to a value higher than the voltage supplied to the sense amplifier during the ordinary sense operation.

Dynamic random-access memories (DRAMs) are being widely used as a semiconductor memory device. Various overdrive techniques have been proposed with respect to DRAMs. Description will be below made of overdrive techniques with respect to a semiconductor memory device assumed to be a DRAM.

Japanese Patent Laid-Open Nos. 2000-243085 and 11-39875 (JP-A-2000-243085 and JP-A-11-039875) disclose an external power supply direct coupling scheme as a scheme for realizing overdrive. In this external power supply direct coupling scheme, a sense amplifier is driven by an external power supply voltage VDD only during a period in an initial stage of the operation of the sense amplifier. After a lapse of a predetermined time period from a start of the drive, the sense amplifier is driven by an internal stepped-down voltage. A lapse of the predetermined time period is detected by using a delay circuit.

FIG. 1 is a circuit diagram showing the configuration of a memory array section in a semiconductor memory device (in this case, a DRAM) in a related art realizing overdrive by the external power supply direct coupling scheme.

Memory cell 10 is connected to a corresponding bit line BL via memory transistor 13. The gate of memory transistor 13 is connected to a word line WL. Needless to say, while only one memory cell 10 is illustrated, a memory cell array is configured in such a manner that a multiplicity of memory cells 10 are arranged in the form of a two-dimensional array and bit lines BL and word lines WL are laid in matrix form.

Sense amplifier 12 is provided in correspondence with each pair of bit lines BL and is connected to the pair of bit lines. Sense amplifier 12 is of an ordinary configuration and is supplied with a power supply voltage via common source lines PCS and NCS. The common source line NCS on the lower-potential side is connected to a ground potential via transistor 14 gate-controlled by a control signal SAN.

Internal power supply generation circuit 11 is provided which generates an array voltage VARY as an internal stepped-down voltage by reducing an external power supply voltage VDD. The array voltage VARY is supplied to the common source line PCS on the higher-potential side via switching transistor 16. The external power supply voltage VDD is also supplied to the common source line PCS on the higher-potential side via switching transistor 15. Delay circuit 17, AND (logical multiplication) circuit 18 and NOT (logical negation) circuit 19 are provided to control these transistors 15 and 16. More specifically, this control is performed in such a manner that the external power supply voltage VDD is supplied to the common source line PCS by setting transistor 15 in the on state and setting transistor 16 in the off state in an initial stage of sense operation, and the array voltage VARY is supplied to the common source line PCS by setting transistor 15 in the off state and setting transistor 16 in the on state after a lapse of a predetermined time period. A control signal SAE for enabling the sense amplifier is supplied to delay circuit 17 and to one input terminal of AND circuit 18. An output from delay circuit 17 is supplied to the other input terminal of AND circuit 18 and to NOT circuit 19. An output from AND circuit 18 is supplied as a signal SAP1 to the gate of transistor 15, while an output from NOT circuit 19 is supplied as a signal SAP2 to the gate of transistor 16.

The operation of the circuit shown in FIG. 1 will be described with reference to FIG. 2.

It is assumed here that a potential equivalent to the voltage VARY is stored in memory cell 10 and a state of high level is established in binary states. In the description made below, the state corresponding to high level in the binary states in the memory cell is expressed by “(H),” while the other state is expressed by “(L).” In an initial state before a start of the sense operation, each of the common source lines NCS and PCS and the bit lines BL(H) and BL(L) is charged to a potential of VARY/2. Each of the signals SAP1 and SAP2 is low level and each of transistors 15 and 16 is in the off state.

The word line WL is activated at time T0. The bit line BL(H) is then charged by the potential stored in memory cell 10 in the state of high level (H) to produce a potential difference between the bit line BL(H) and the bit line BL(L). This potential difference is increased by the sense operation. The control signal SAN rises at time T1. The potential on the common source line NCS on the lower-potential side is thereby pulled to low level “L” and sense amplifier 12 starts amplifying operation, such that the potential on the bit line BL(L) is pulled to the potential on the common source line NCS due to the potential difference between the bit lines BL(H) and BL(L). The control voltage SAE rises simultaneously with the rise of the control voltage SAN, causing the signal SAP1 to rise to set transistor 15 in the on state. The common source line PCS is thereby charged to the external power supply voltage VDD. With this charging, the bit line BL(H) is also charged. The target potential to which the bit line BL(H) is to be charged at this time is the array voltage VARY. This charging can be performed by using a voltage higher than the array voltage VARY to accelerate the sense operation. This is the technique called overdrive.

After a lapse of a certain time period (at time T2) after the start of the overdrive, delay circuit 17 causes a fall of the signal SAP1 and at the same time a rise of the signal SAP2. Transistors 15 and 16 are thereby set in the off state and in the on state, respectively. As a result, the potential on the common source line PCS drops from the external power supply voltage VDD to the array voltage VARY potential, and the potential on the bit line BL(H) is settled at the potential at VARY. In this overdrive operation, the period during which the signal SAP1 is “H” is referred to as “overdrive period.”

In the overdrive technique described above with reference to FIGS. 1 and 2, the sense operation is accelerated by using an external power supply voltage. If the external power supply voltage varies, the boosting effect of the bit line BL by overdrive is changed and there is a possibility of the final potential on the bit line BL(H) becoming excessively higher or excessively lower than the array voltage VARY. That is, the external power supply voltage VDD varies, a problem arises that the operation margin of the sense amplifier is considerably reduced. This problem becomes more serious with reduction in voltage, for example, when the external power supply voltage is reduced to 1 V.

To solve this problem, an on-chip power supply circuit which generates an overdrive voltage VOD higher than the array voltage VARY may be provided in the DRAM. In an initial state of sense operation, this overdrive voltage VOD is supplied to each sense amplifier instead of the array voltage VARY. In this case, the load drive capacity of the on-chip power supply circuit for generating the overdrive voltage VOD is insufficient for the load capacitance. There is, therefore, a need to add an on-chip capacitive element (i.e., capacitor) to the output section of this on-chip power supply circuit.

Since the charge supplied to the common source line PCS for drive of sense amplifiers is used to charge a predetermined number of bit lines through the sense amplifiers, the sum of the electrical capacitances of the bit lines to be charged can be regarded as the load capacitance. If charge is transferred between the on-chip capacitive element and the load capacitance defined as described above, the potential on the bit lines can be made to reach the desired voltage (VARY) at a high speed. In this case, the output terminal of the on-chip power supply circuit and the capacitive element operate in a floating system, such that the on-chip power supply circuit is normally disconnected electrically from the capacitive element and the sense amplifier side, and is electrically connected to the capacitive element only at a time at which the capacitive element is to be charged. That is, the on-chip capacitive element is charged in advance by the on-chip power supply circuit, the connection between the on-chip power supply circuit and the capacitive element is cut immediately before drive of the sense amplifier. Drive of the sense amplifier is then started. This scheme for realizing overdrive is called “internal power supply capacitive charge sharing scheme.”

FIG. 3 is a circuit diagram showing the configuration of a memory array section in a semiconductor memory device (in this case, a DRAM) in a related art realizing overdrive by the internal power supply capacitive charge sharing scheme. The circuit shown in FIG. 3 is similar to the circuit shown in FIG. 1 but differs from the same in that transistor 15 is not connected to the external power supply voltage VDD but connected to internal power supply generation circuit 21, which generates an overdrive voltage VOD as an internal stepped-down voltage by reducing the external power supply voltage VDD. Here, the overdrive voltage VOD is higher than the array voltage VARY. Capacitive element (i.e., capacitor) 20 having a capacitance q is provided at the output of internal power supply generation circuit 21. The operation of internal power supply generation circuit 21 is controlled by an on/off signal externally supplied. When internal power supply generation circuit 21 is in the disabled state (i.e., off state), the output from circuit 21 is set in the floating state and disconnected from capacitive element 20 side.

The operation of the circuit shown in FIG. 3 will be described with reference to FIG. 4.

It is assumed that a potential equivalent to the voltage VARY is stored in memory cell 10 and a state of high level is established in binary states, as in the operation shown in FIGS. 1 and 2. In an initial state before a start of the sense operation, each of the common source lines NCS and PCS and the bit lines BL(H) and BL(L) is charged to a potential of VARY/2. Each of the signals SAP1 and SAP2 is low level and each of transistors 15 and 16 is in the off state. Also, the potential VOD is stored in capacitive element 20 and internal power supply generation circuit 21 is in the disabled state.

The operation before a start of the sense operation is the same as that shown in FIG. 2. When the signal SAP1 rises, the common source line PCS and the bit line BL(H) are charged by the charge accumulated in capacitive element 20 to effect charge sharing between capacitive element 20 charged to the potential VOD and the bit line BL(H). The potential on capacitive element 20 and the potential on the bit line BL(H) are set to a common potential (referred to as “charge sharing voltage”) by charge sharing. The capacitance q of capacitive element 20 is set so that the charge sharing voltage equals the array voltage VARY. After the end of the overdrive period, capacitive element 20 is electrically disconnected from the common source line PCS by transistor 15. Internal power supply generation circuit 21 is then set in the enabled state (i.e., on state) to charge capacitive element 20 at time T3. Internal power supply generation circuit 21 is maintained in the enable state until the voltage across capacitive element 20 becomes equal to the predetermined overdrive voltage VOD. After the voltage across capacitive element reaches the overdrive voltage VOD, Internal power supply generation circuit 21 is disabled again.

In this overdrive by the internal power supply capacitive charge sharing scheme, the capacitance q of capacitive element 20 is set according to the VARY potential. Therefore the VARY potential cannot be increased. If the VARY potential is increased by newly setting the capacitance value of capacitive element 20, the necessary capacitance of capacitive element 20 becomes much higher, which is considerably disadvantageous from the viewpoint of an area condition for the DRAM.

Table 1 shows the relationship between the VARY potential and the capacitance. In Table 1, “bit line capacitance” in column (a) and “sense amplifier capacitance” in column (b) denote a capacitance per bit line and a capacitance per sense amplifier, respectively.

TABLE 1

| | | | | | (f) | (g) | | |
|---|---|---|---|---|---|---|---|---|
| | (b) | | | | Capacitance | Current | (h) | |
| (a) | Sense | (c) | | | required of | capacitance | Charge | |
| Bit line | amplifier | Total | (d) | (e) | capacitive | of capacitive | sharing | (i) |
| capacitance | capacitance | capacitance | VARY | VOD | element | element | voltage | (h) − (d) |
| [fF] | [fF] | [pF] | [V] | [V] | [pF] | [pF] | [V] | [mV] |
| 50 | 10 | 506.9 | 1.0 | 1.35 | 724.1 | 750 | 1.007 | +7 |
| 50 | 10 | 506.9 | 1.1 | 1.35 | 1115.1 | 750 | 1.027 | −73 |
| 50 | 10 | 506.9 | 1.2 | 1.35 | 2027.5 | 750 | 1.048 | −152 |

A 64-megabits DRAM is assumed here and it is assumed that the 64-megabits array is divided into 24×16 mats and 352 sense amplifiers are provided on each mat. If the capacitance per bit line is 50 fF and the capacitance per sense amplifier is 10 fF, 352×24 sense amplifiers operate in one cycle of sense operation and the total capacitance to be charged in one cycle of sense operation (column (c) in Table 1) is represented as:

Total capacitance=(50 fF+10 fF)×(352×24)=506.9 pF.

If the VARY potential (column (d) in Table 1) is 1.0 V and the VOD potential (column (e) in Table 1) is 1.35 V, the capacitance q required of capacitive element 20 (column (f) in Table 1) is represented as:

$$q = \frac{\{ 506.9 pF \times ( 1.0 V - \frac{1.0 V}{2} ) \}}{( 1.35 V - 1.0 V )} = 724.1 pF .$$

If the VARY potential (column (d) in Table 1) is set to 1.2 V, an enormous capacitance:

$$q = \frac{\{ 506.9 pF \times ( 1.2 V - \frac{1.2 V}{2} ) \}}{( 1.35 V - 1.2 V )} = 2027.5 pF$$

is required. If, regarding this, only a capacitor having a capacitance of 750 pF (column (g) in Table 1) can be provided as on-chip capacitive element 20 due to the area condition in the layout of the DRAM, the charge sharing voltage (column (h) in Table 1) is represent as:

$$\begin{matrix}Charge sharing voltage = \frac{( 506.9 pF \times \frac{1.2 V}{2} ) + ( 750 pF \times 1.35 V )}{( 506.9 pF + 750 pF )} \\ = 1.048 V ,\end{matrix}$$

and the deficiency with respect to the required VARY potential (column (d) in Table 1) is 152 mV, which is a large amount.

Thus, with overdrive by the internal power supply capacitive charge sharing scheme, there is a problem that a design to increase the voltage VARY requires increasing the capacitance value of the on-chip capacitive element accompanying the internal power supply generation circuit that generates the overdrive voltage VOD. Needless to say, increasing the overdrive voltage VOD is conceivable as a measure to cope with this problem. However, it is not practical to increase the overdrive voltage VOD under the trend toward use of lower external power supply voltage VDD in recent years.

In the above-described semiconductor memory device, increasing the array voltage VARY entails the disadvantage of increasing the consumption current but produces advantageous effects of increasing the speed of sense operation and improving the capability of holding a potential in each memory cell. It is, therefore, desirable to change the array voltage VARY according to the performances of the memory cell and the sense amplifier and required specifications. In the semiconductor memory device using the internal power supply capacitive charge sharing scheme, however, the array voltage VARY cannot be changed because the charge sharing potential is fixed.

As described above, there are several problems with the overdrive technique in the related arts.

The external power supply direct coupling scheme has the problem that a sufficient operation margin for the sense amplifier cannot be maintained with respect to variations in the external power supply voltage. The internal power supply capacitive charge sharing scheme requires a large-capacitance capacitive element accompanying the internal power supply generation circuit which produces the overdrive voltage VOD. This is because capacitive charge sharing is performed and because there is a limit to the potential chargeable on the capacitance of bit lines and so on. The internal power supply capacitive charge sharing echeme also entails a problem that since the charge sharing voltage is fixed because of capacitive charge sharing, the VARY voltage potential cannot be changed as desired.

### SUMMARY OF THE INVENTION

An exemplary object of the present invention is to provide an overdrive-type semiconductor memory device which uses an internal step-down power supply independent of an external power supply voltage, and which does not require an increased capacitance for overdrive voltage VOD.

Another exemplary object of the present invention is to provide an overdrive-type semiconductor memory device which uses an internal step-down power supply independent of an external power supply voltage, and which is capable of increasing array voltage VARY.

Still another exemplary object of the present invention is to provide a method of driving an overdrive-type semiconductor memory device which uses an internal step-down power supply independent of an external power supply voltage, which does not require an increased capacitance for overdrive voltage VOD, and which is capable of increasing array voltage VARY.

According to an exemplary aspect of the present invention, a semiconductor memory device including a memory cell and operating by being supplied with an external power supply voltage is provided. The semiconductor device includes: a first internal power supply generation circuit which generates a first potential lower than the external power supply voltage; a second internal power supply generation circuit which generates a second potential lower than the first potential; a capacitor provided at the output of the first internal power supply generation circuit and charged to the first potential; a bit line connected to the memory cell; a sense amplifier connected to the bit line, performing sense operation on the memory cell to amplify a potential on the bit line to the second potential according to charge accumulated in the memory cell; and a connection control circuit which connects the first internal power supply generation circuit to the sense amplifier during an overdrive period from a moment at which the sense operation is started to a moment at which a first time period from the start of the sense operation lapses, and which connects the second internal power supply generation circuit to the sense amplifier after the lapse of the first time period, wherein the first internal power supply generation circuit is set in an enabled state before the start of the sense operation and is set in a disabled state after the completion of charging of the capacitive element, and the output of the first internal power supply generation circuit is thereby set in a floating state.

According to another exemplary aspect of the present invention, a method of driving a semiconductor memory device including a memory cell, a first internal power supply generation circuit which generates a first potential lower than an external power supply voltage supplied from the outside, a second internal power supply generation circuit which generates a second potential lower than the first potential, a capacitor provided at an output of the first internal power supply generation circuit and charged to the first potential, a bit line connected to the memory cell, and a sense amplifier connected to the bit line, performing sense operation on the memory cell to amplify a potential on the bit line to the second potential according to charge accumulated in the memory cell is provided. The method includes: connecting the first internal power supply generation circuit to the sense amplifier during an overdrive period from a moment at which the sense operation is started to a moment at which a first time period from start of the sense operation lapses; disconnecting the first internal power supply generating circuit from the sense amplifier and connecting the second internal power supply generation circuit to the sense amplifier after the lapse of the first time period; setting the first internal power supply generation circuit in an enabled state before the start of the sense operation; and setting the first internal power supply generation circuit in a disabled state after completion of charging of the capacitor and thereby setting the output of the first internal power supply generation circuit in a floating state.

According to the present invention, even in a situation where the second potential, i.e., array voltage VARY, is so high that the charge sharing voltage on the capacitance of the bit line and the capacitance of the capacitor does not reach array voltage VARY, the bit line is pulled to VARY potential by the first internal power supply generation circuit which generates the first potential, i.e., overdrive voltage VOD. Array voltage VARY can be increased in this way and the capacitance of the capacitor can be reduced.

The above and other objects, features, and advantages of the present invention will become apparent from the following description based on the accompanying drawings which illustrate examples of preferred embodiments of the present invention.

### BRIEF DESCRIPTION OF THE DRAWINGS

FIG. 1 is a circuit diagram showing an example of an array circuit which is provided in a semiconductor memory device and which uses an external power supply direct coupling scheme to realize overdrive;

FIG. 2 is a waveform diagram showing the operation of the circuit shown in FIG. 1;

FIG. 3 is a circuit diagram showing an example of an array circuit which is provided in a semiconductor memory device and which uses an internal power supply capacitive charge sharing scheme to realize overdrive;

FIG. 4 is a waveform diagram showing the operation of the circuit shown in FIG. 3;

FIG. 5 is a block diagram showing an example of an array circuit using an overdrive technology which is provided in a semiconductor memory device according to an exemplary embodiment of the present invention;

FIG. 6 is a waveform diagram showing the operation of the circuit shown in FIG. 5;

FIG. 7 is a circuit diagram showing an example of a configuration of a delay circuit;

FIG. 8 is a circuit diagram showing an example of a delay element using resistors and capacitive elements; and

FIG. 9 is a diagram showing a layout of a memory cell array in the semiconductor memory device according to the exemplary embodiment.

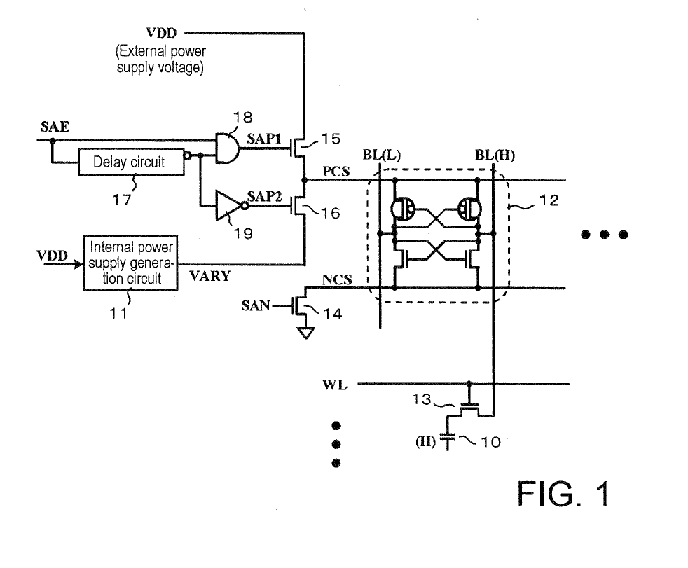

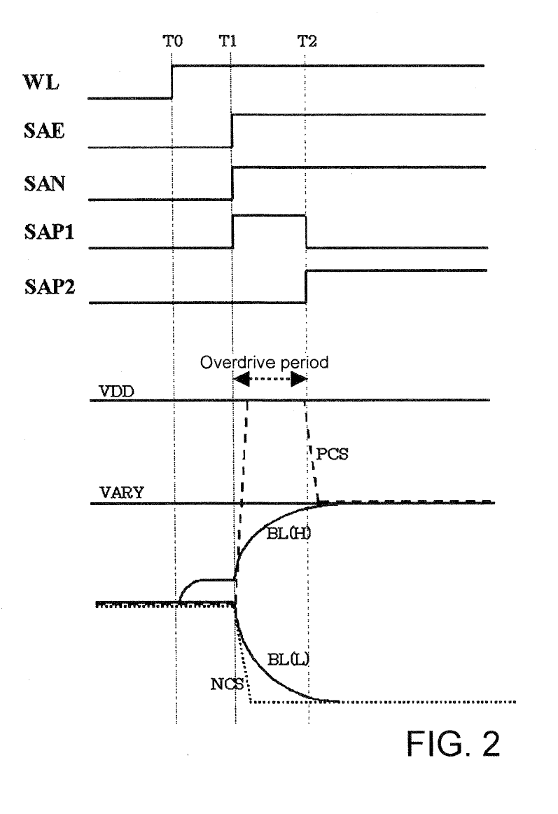

### DETAILED DESCRIPTION OF THE EXEMPLARY EMBODIMENT

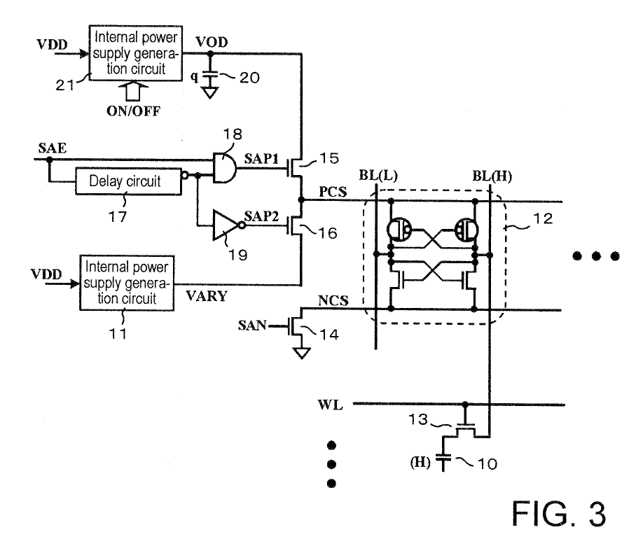

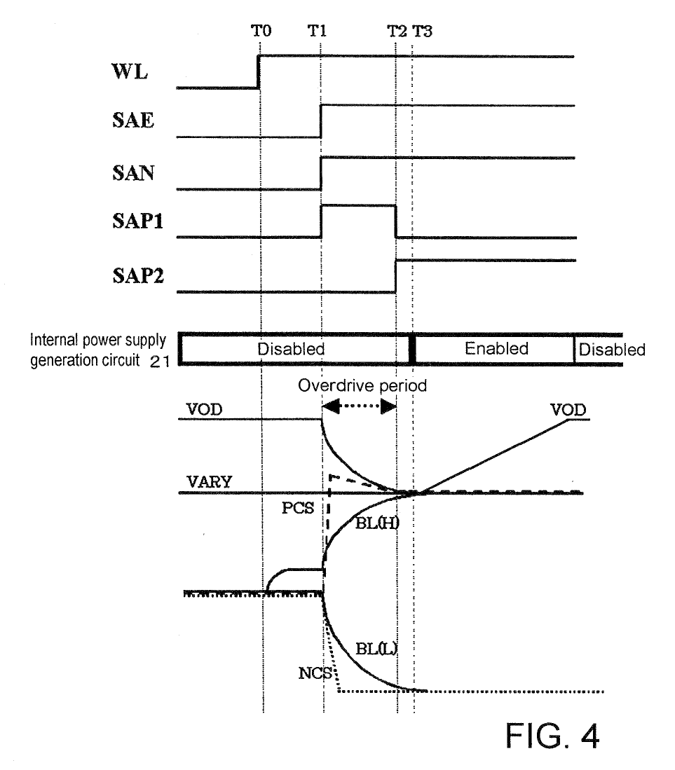

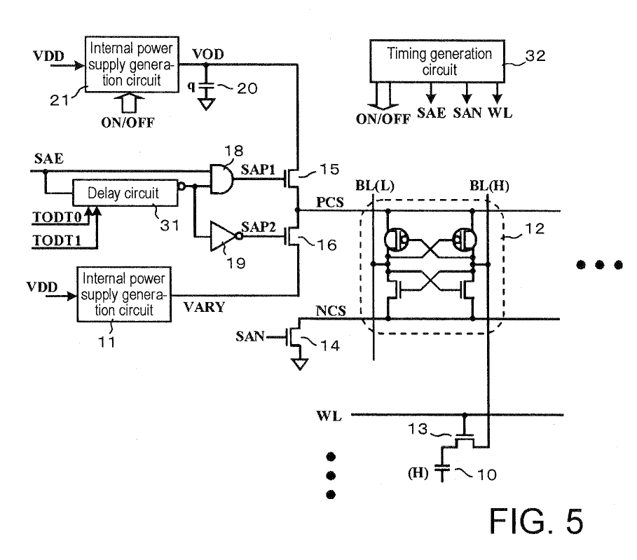

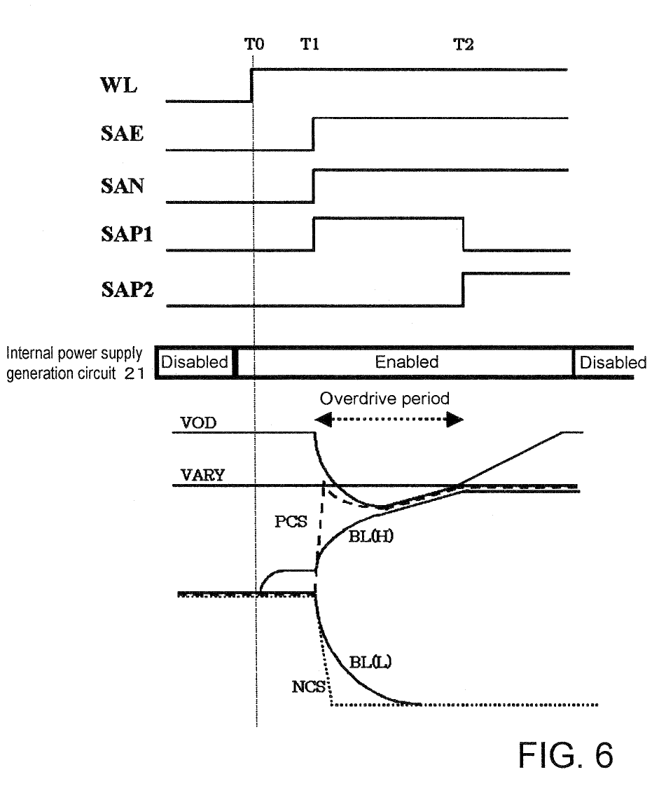

FIG. 5 shows an example of an array circuit using an overdrive in a semiconductor memory device according to an exemplary embodiment of the present invention. Description will be made by assuming that the semiconductor memory device is a DRAM. The circuit shown in FIG. 5 is similar to the circuit shown in FIG. 3, in which overdrive according to the internal power supply capacitive charge sharing scheme is executed, but differs from the circuit shown in FIG. 3 in operation timing in internal power supply generation circuit 21 for generating overdrive voltage VOD as an internal stepped-down voltage from external power supply voltage VDD, and also differs from the circuit shown in FIG. 3 in that delay circuit 31 is capable of changing the delay time. FIG. 6 shows operating waveforms in the circuit shown in FIG. 5.

Since the semiconductor memory device in the present exemplary embodiment is a DRAM, memory cell 10 is a dynamic-type memory cell. In the circuit shown in FIG. 5, transistors 15 and 16, AND circuit 18, NOT circuit 19 and delay circuit 31 constitutes a connection control circuit. This connection control circuit operates on the basis of the control signal SAE to connect internal power supply generation circuit 21 to sense amplifier 12 during an overdrive period from a moment at which sense operation is started to a moment at which a first time period from the start of the sense operation lapses and to connect internal power supply generation circuit 11 to sense amplifier 12 after the lapse of the first time period. FIG. 5 also shows timing generation circuit 32 which drives word lines WL and generates an on/off signal and control signals SAE and SAN. The on/off signal is supplied to internal power supply generation circuit 21. In the present exemplary embodiment, internal power supply generation circuit 21 is a first internal power supply generation circuit generating the overdrive voltage VOD and internal power supply generation circuit 11 is a second internal power supply generation circuit generating the array voltage VARY.

In the semiconductor memory device in which overdrive according to the internal power supply capacitive charge sharing scheme is executed, the internal power supply generation circuit for producing overdrive voltage VOD is set in the disabled state (i.e., off state) during sense operation and is set in the enabled state (i.e., on state) after the completion of overdrive. On the other hand, in the semiconductor memory device according to the present exemplary embodiment, internal power supply generation circuit 21 for generating the overdrive voltage VOD is set in the enabled state before a start of sense operation, more specifically at a time immediately before time T0 at which the word line WL is activated. At the time at which internal power supply generation circuit 21 is set in the enabled state, capacitive element (i.e., capacitor) 20 has already been in the charged state at the set value, i.e., the overdrive voltage VOD. Therefore, substantially no current is supplied from internal power supply generation circuit 21 before a start of sense operation, i.e., before time T1.

In a case where the array voltage VARY is increased in the semiconductor memory device using the internal power supply capacitive charge sharing scheme, on the start of sense operation, charge sharing is performed between capacitive element 20 and the bit line BL(H) at a potential lower than the voltage VARY because the capacitance q of capacitive element 20 is insufficient. In contrast, in the circuit according to the present exemplary embodiment, internal power supply generation circuit 21 is operating during sense operation, and the voltage on capacitive element 20 drops below the set value after time T1, and, therefore, the bit line BL and capacitive element 20 are charged by current supply from internal power supply generation circuit 21. The overdrive period is set longer than that in the case of a setting of lower voltage VARY so that overdrive ends at a time at which the potential on the bit line BL(H) reaches the array voltage VARY. The length of the overdrive period can be easily adjusted through adjustment of the amount of internal delay given by the delay circuit. The amount of internal delay can be adjusted with accuracy by using delay circuit 31 in the present exemplary embodiment, as described below.

Thus, in the semiconductor memory device according to the present exemplary embodiment, even in a case where the array voltage VARY is changed, the overdrive period is adjusted to enable the sense operation using overdrive without changing the capacitance q of capacitive element 20 connected to internal power supply generation circuit 21 generating overdrive voltage VOD. The operation after the completion of overdrive is the same as that in the internal power supply capacitive charge sharing scheme described above except that internal power supply generation circuit 21 is already set in the enabled state.

In this semiconductor memory device, internal power supply generation circuit 21 is set in the enable state before the start of sense operation by timing generation circuit 32 and is set in the disabled state after the completion of charging of capacitive element 20 and the output of internal power supply generation circuit 21 is set in the floating state.

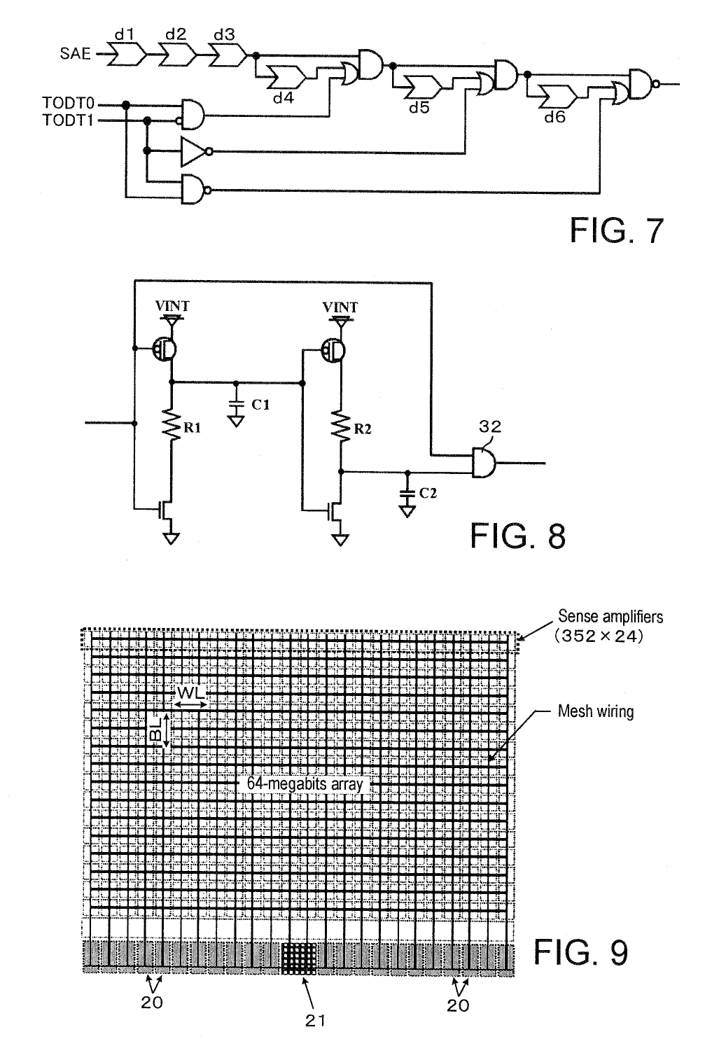

FIG. 7 is a diagram showing the internal configuration of delay circuit 31 used in the semiconductor memory device according to the present exemplary embodiment. Delay circuit 31 is capable of changing the amount of internal delay, i.e., the delay time, in four steps and is used for adjustment of the overdrive period. Test mode signals TODT0 and TODT1 of two bits for delay time selection are supplied to delay circuit 31.

Delay circuit 31 is of a configuration in which six delay elements d1 to d6 are connected in series. Delay elements d1 to d6 are identical in configuration to each other. Of these delay elements, three delay elements d1 to d3 are enabled at all times, while the enabled (i.e., valid) or disabled (i.e., invalid) state of the other three delay elements d4 to d6 is determined on the basis of the test mode signals TODT0 and TODT1 by inserting AND-OR circuits between these delay elements. Table 2 is a truth table of the circuit shown in FIG. 7.

TABLE 2

| TODT0 | TODT1 | d4 | d5 | d6 |
|---|---|---|---|---|
| L | L | Enabled | Disabled | Disabled |
| L | H | Enabled | Enabled | Disabled |
| H | L | Disabled | Disabled | Disabled |
| H | H | Enabled | Enabled | Enabled |

In the circuit shown in FIG. 7, selection from “none of the delay elements is enabled”, “only one of the elements is enabled”, “only two of the elements are enabled” and “all the three elements are enabled” can be made with respect to the three delay elements d4 to d6 according to a combination of “H” and “L” of the test mode signals TODT0 and TODT1. Thus, delay circuit 31 is capable of selecting from four different numbers, 3 to 6, of delay element stages connected in series by using the test mode signals TODT0 and TODT1. As a result, in the circuit shown in FIG. 5, the overdrive period can be selected from the four delay values.

FIG. 8 is a circuit diagram showing the internal circuit configuration of each of the delay elements d1 to d6. An internal constant voltage VINT is supplied from an internal constant-voltage source in order to reduce a power supply voltage dependence. Two stages of CMOS (complementary MOS) inverters incorporating CR (capacitor-resistor) integration circuits therein are connected in series, and AND circuit 32 is also provided to which an input to the first-stage CMOS inverter and an output from the second-stage CMOS inverter are supplied. The input to the first-stage inverter is an input to this delay element, and an output from AND circuit 32 is an output from this delay element. Variation in delay amount due to manufacturing variation is limited by using the CR integration circuits formed of resistors R1 and R2 and capacitors C1 and C2. The delay amount is determined on the basis of the values of these resistors and capacitive elements. As resistors R1 and R2 in particular, not resistors formed by using the resistance of the channel region of a MOS transistor but resistors formed of a wiring material of small manufacturing variation are used, thereby realizing a delay element with a constant delay substantially unsusceptible to manufacturing variations in transistors.

FIG. 9 shows a layout of the memory cell array in the semiconductor memory device according to the present exemplary embodiment. Capacitive elements 20 are arranged at one end of a 64-megabits array, and internal power supply generation circuit 21 is placed at a center of the arrangement of capacitive elements 20. Since capacitive elements 20 are charged from internal power supply generation circuit 21, the placement of internal power supply generation circuit 21 at a center of the arrangement of capacitive elements 20 is preferred as shown in FIG. 9. As described above, the 64-megabits array is divided into 24×16 mats, and 352 sense amplifiers are provided on each mat. Capacitive elements 20 and internal power supply generation circuit 21 are connected to the mats by mesh wiring. Since the common source lines (i.e., drive lines) and bit lines BL connected to the sense amplifiers are charged by charge sharing at the time of sense operation, it is preferable to arrange the common source line in such mesh form. When a word line WL is activated, the 24 mats along the word line WL direction are operated and, accordingly, 8448 (=352×24) sense amplifiers are operated. In a case where overdrive according to the internal power supply capacitive charge sharing scheme is performed, there is a need to provide capacitive elements having capacitances matching the capacitances of such a large number of sense amplifiers and bit lines connected to the sense amplifiers. According to the method in the present exemplary embodiment, the capacitances of the capacitive elements are minimized to reduce the area for the capacitive elements in the DRAM layout.

The exemplary embodiment of the present invention has been described with respect to a case where the semiconductor memory device is a DRAM. However, the semiconductor memory device to which the overdrive technique based on the present invention is applied is not limited to the DRAM.

While exemplary embodiments of the present invention have been described using specific terms, such description is for illustrative purposes only, and it is to be understood that changes and variations may be made without departing from the spirit or scope of the following claims.

What is claimed is:

1. A semiconductor memory device including a memory cell and operating by being supplied with an external power supply voltage, the semiconductor device comprising:
a first internal power supply generation circuit which generates a first potential lower than the external power supply voltage;
a second internal power supply generation circuit which generates a second potential lower than the first potential;
a capacitor provided at an output of the first internal power supply generation circuit and charged to the first potential;
a bit line connected to the memory cell;
a sense amplifier connected to the bit line, performing sense operation on the memory cell to amplify a potential on the bit line to the second potential according to charge accumulated in the memory cell; and
a connection control circuit which connects the first internal power supply generation circuit to the sense amplifier during an overdrive period from a moment at which the sense operation is started to a moment at which a first time period from start of the sense operation lapses, and which connects the second internal power supply generation circuit to the sense amplifier after the lapse of the first time period,
wherein the first internal power supply generation circuit is set in an enabled state before the start of the sense operation and is set in a disabled state after completion of charging of the capacitor, and the output of the first internal power supply generation circuit is thereby set in a floating state.

2. The semiconductor memory device according to claim 1, wherein the first and second internal power supply generation circuits are supplied with the external power supply voltage and generate the first and second potentials, respectively, by stepping down the external power supply voltage.

3. The semiconductor memory device according to claim 1, wherein the connection control circuit includes a first switch provided between the output of the first internal power supply generation circuit and the sense amplifier, a second switch provided between an output of the second internal power supply generation circuit and the sense amplifier, and a delay circuit which, to detect the lapse of the first time period, starts delay operation at the moment at which the sense operation is started, and wherein the first and second switches are controlled based on an output of the delay circuit.

4. The semiconductor memory device according to claim 3, wherein each of the first and second switch comprises a transistor.

5. The semiconductor memory device according to claim 3, wherein the delay circuit is capable of adjusting delay time thereof according to an external signal.

6. The semiconductor memory device according to claim 2, wherein the connection control circuit includes a first switch provided between the output of the first internal power supply generation circuit and the sense amplifier, a second switch provided between an output of the second internal power supply generation circuit and the sense amplifier, and a delay circuit which, to detect the lapse of the first time period, starts delay operation at the moment at which the sense operation is started, and wherein the first and second switches are controlled based on an output of the delay circuit.

7. The semiconductor memory device according to claim 6, wherein each of the first and second switch comprises a transistor.

8. The semiconductor memory device according to claim 6, wherein the delay circuit is capable of adjusting delay time thereof according to an external signal.

9. The semiconductor memory device according to claim 1, wherein the memory cell is a dynamic-type memory cell.

10. A method of driving a semiconductor memory device including a memory cell, a first internal power supply generation circuit which generates a first potential lower than an external power supply voltage supplied from the outside, a second internal power supply generation circuit which generates a second potential lower than the first potential, a capacitor provided at an output of the first internal power supply generation circuit and charged to the first potential, a bit line connected to the memory cell, and a sense amplifier connected to the bit line, performing sense operation on the memory cell to amplify a potential on the bit line to the second potential according to charge accumulated in the memory cell, the method comprising:
connecting the first internal power supply generation circuit to the sense amplifier during an overdrive period from a moment at which the sense operation is started to a moment at which a first time period from start of the sense operation lapses;
disconnecting the first internal power supply generating circuit from the sense amplifier and connecting the second internal power supply generation circuit to the sense amplifier after lapse of the first time period;
setting the first internal power supply generation circuit in an enabled state before the start of the sense operation; and
setting the first internal power supply generation circuit in a disabled state after completion of charging of the capacitor and thereby setting the output of the first internal power supply generation circuit in a floating state.

11. The method of driving according to claim 10, wherein the memory cell is a dynamic-type memory cell.
